(19) United States
(12) Patent Application Publication
(10) Pub. No.: US 2019/0305152 A1
(43) Pub. Date: Oct. 3, 2019

(54) SOLAR CELL MODULE AND METHOD OF MANUFACTURING A SOLAR CELL MODULE

(71) Applicant: Panasonic Intellectual Property Management Co., Ltd., Osaka (JP)

(72) Inventor: Keiichiro MASUKO, Osaka (JP)

(21) Appl. No.: 16/442,219

(22) Filed: Jun. 14, 2019

Related U.S. Application Data
(63) Continuation of application No. PCT/JP2017/039398, filed on Oct. 31, 2017.

(30) Foreign Application Priority Data
Dec. 20, 2016 (JP) 2016-247069

(51) Int. Cl. H01L 31/0224; H01L 31/05

(52) U.S. Cl. CPC H01L 31/022425; H01L 31/05

(57) ABSTRACT

A solar cell module includes: a first solar cell having a first principal surface on which n-side and p-side electrodes are provided; a second solar cell having a second principal surface on which n-side and p-side electrodes are provided; a connection member that connects the first principal surface and the second principal surface; a first conductive adhesion part that connects the n-side electrode of the first solar cell with the connection member; a second conductive adhesion part that connects the p-side electrode of the second solar cell with the connection member; and an intermediate insulation part that is provided at a position on a surface of the connection member between the first conductive adhesion part and the second conductive adhesion part and is provided at a distance from at least one of the first solar cell and the second solar cell.

### RELATED APPLICATION

Priority is claimed to Japanese Patent Application No. 2016-247069, filed on Dec. 20, 2016, the entire content of which is incorporated herein by reference.

### BACKGROUND

### Field of the Invention

The present disclosure relates to a solar cell module and a method of manufacturing a solar cell module.

### Description of the Related Art

A solar cell is modularized by connecting a plurality of cells. In the case of using a back-contact solar cell including n-type electrodes and p-type electrodes on the back surface, adjacent cells are connected by means of a connection member provided on the back surface side of the cell.

It is preferred to prevent contact between cells connected by a connection member and contact between a cell and a connection member at a location outside the electrode that should be connected.

### SUMMARY

The disclosure addresses the above-described issue, and a general purpose thereof is to provide a solar cell module that is highly reliable.

A solar cell module according to an embodiment of the disclosure includes: a first solar cell in which an n-side electrode and a p-side electrode are provided on one principal surface; a second solar cell in which an n-side electrode and a p-side electrode are provided on one principal surface; a connection member that connects the one principal surface of the first solar cell and the one principal surface of the second solar cell and electrically connects the n-side electrode of the first solar cell and the p-side electrode of the second solar cell; a first conductive adhesion part that connects the n-side electrode of the first solar cell with the connection member; a second conductive adhesion part that connects the p-side electrode of the second solar cell with the connection member; and an intermediate insulation part that is provided at a position on a surface of the connection member between the first conductive adhesion part and the second conductive adhesion part and is provided at a distance from at least one of the first solar cell and the second solar cell.

Another embodiment of the present disclosure relates to a method of manufacturing a solar cell module. The method includes: forming an intermediate insulation part on a surface of a connection member for connecting one principal surface of a first solar cell including an n-side electrode and a p-side electrode on the one principal surface and one principal surface of a second solar cell including an n-side electrode and a p-side electrode on the one principal surface; connecting, via a first conductive adhesion part, the n-side electrode of the first solar cell at a position on the surface of the connection member different from a position of the intermediate insulation part; and connecting, via a second conductive adhesion part, the p-side electrode of the second solar cell at a position on the surface of the connection member opposite to the first conductive adhesion part, sandwiching the intermediate insulation part.

### BRIEF DESCRIPTION OF THE DRAWINGS

The figures depict one or more implementations in accordance with the present teaching, by way of example only, not by way of limitations. In the figures, like reference numerals refer to the same or similar elements.

FIG. 1 is a cross sectional view showing a structure of a solar cell module according to an embodiment;

FIG. 2 is a plan view showing solar cells connected by a connection member;

FIG. 3 is a plan view showing solar cells connected by a connection member;

FIG. 4 is a plan view schematically showing an arrangement of the conductive adhesion part and the insulation part;

FIGS. 5A-5C are cross-sectional views schematically showing steps of manufacturing the solar cell module;

FIG. 6 is a cross-sectional view schematically showing a step of manufacturing the solar cell module;

FIGS. 7A-7C are cross-sectional views schematically showing steps of manufacturing the solar cell module according to a variation;

FIG. 8 is a plan view schematically showing a configuration of a connection member according to a variation;

FIG. 9 is a plan view schematically showing a configuration of an intermediate insulation part according to a variation; and

FIG. 10 is a plan view schematically showing a configuration of an intermediate insulation part according to another variation.

### DETAILED DESCRIPTION

The invention will now be described by reference to the preferred embodiments. This does not intend to limit the scope of the present invention, but to exemplify the invention.

A brief summary will be given before giving the disclosure in specific details. An embodiment of the disclosure relates to a solar cell module. The solar cell module includes: a first solar cell in which an n-side electrode and a p-side electrode are provided on one principal surface; a second solar cell in which an n-side electrode and a p-side electrode are provided on one principal surface; a connection member that connects the one principal surface of the first solar cell and the one principal surface of the second solar cell and electrically connects the n-side electrode of the first solar cell and the p-side electrode of the second solar cell; a first conductive adhesion part that connects the n-side electrode of the first solar cell with the connection member; a second conductive adhesion part that connects the p-side electrode of the second solar cell with the connection member; and an intermediate insulation part that is provided at a position on a surface of the connection member between the first conductive adhesion part and the second conductive adhesion part and is provided at a distance from at least one of the first solar cell and the second solar cell. According to the embodiment, the intermediate insulation part provided between the first solar cell and the second solar cell prevents connection between the cells and contact between the cell and the connection member. Further, the gap between the solar cell and the connection member is pervaded by the encapsulant for modularization, by providing the intermediate insulation part at a distance from at least one of the cells. In this way, the reliability of the solar cell module is improved.

A detailed description will be given of an embodiment of the disclosure with reference to the drawings. In the explanations of the figures, the same elements shall be denoted by the same reference numerals, and duplicative explanations will be omitted appropriately.

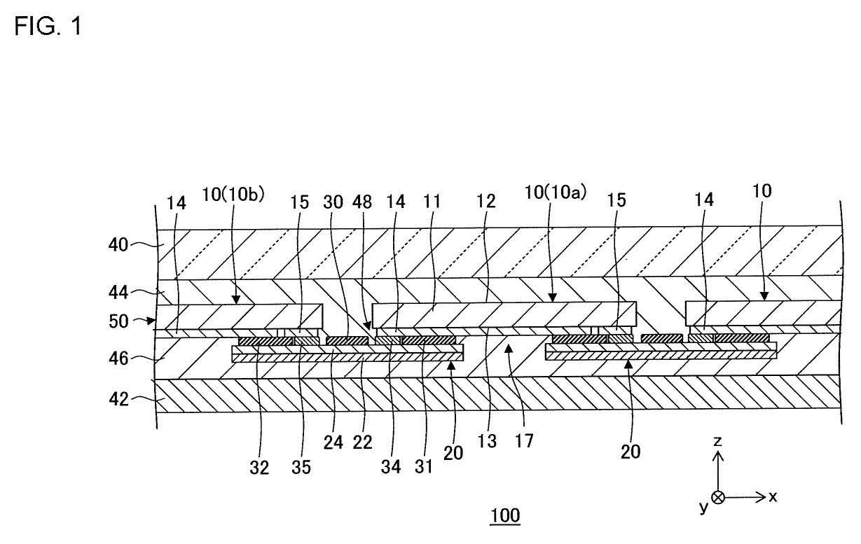

FIG. 1 is a cross sectional view showing a structure of a solar cell module 100 according to an embodiment. The solar cell module 100 includes a first protective member 40, a second protective member 42, a first encapsulant 44, a second encapsulant 46, and a cell string 50. The cell string 50 includes a plurality of solar cells 10, a connection member 20, an intermediate insulation part 30, a first insulation part 31, a second insulation part 32, a first conductive adhesion part 34, a second conductive adhesion part 35.

Referring to FIG. 1, the direction in which the plurality of solar cells 10 included in the cell string 50 are arranged is defined as the x direction, and the direction in which the first protective member 40, the second protective member 42, and the cell string 50 are stacked is defined as the z direction. The direction orthogonal to both the x direction and the z direction is defined as the y direction.

The solar cell 10 includes a photoelectric conversion part 11, an n-side electrode 14 and a p-side electrode 15. The solar cell 10 is a so-called back-contact solar cell, and both the n-side electrode 14 and the p-side electrode 15 are provided on a back surface 13 opposite to a light receiving surface 12. An electrode structure including the n-side electrode 14 and the p-side electrode 15 is not provided on the light receiving surface 12. The photoelectric conversion part 11 includes a semiconductor substrate, an n-type semiconductor layer provided in a partial area (also called an n-type area) on one principal surface of the semiconductor substrate and a p-type semiconductor layer provided in an area (also called a p-type area) on the one principal surface of the semiconductor substrate different from that of the n-type semiconductor layer. The n-side electrode is provided on the n-type semiconductor layer of the photoelectric conversion part 11, and the p-side electrode 15 is provided on the p-type semiconductor layer of the photoelectric conversion part 11. The thickness of the solar cell 10 is, for example, 50-250 μm.

The connection member 20 connects two adjacent solar cells 10. The connection member 20 connects, for example, a first solar cell 10a and a second solar cell 10b adjacent to the first solar cell 10a. The connection member 20 electrically connects the n-side electrode 14 of the first solar cell 10a and the p-side electrode 15 of the second solar cell 10b. The connection member 20 electrically connects the plurality of solar cells 10 included in the cell string 50 in series. The connection member 20 may electrically connect adjacent solar cells 10 in parallel. For example, the connection member 20 may connect the n-side electrodes 14 of the adjacent solar cells 10 mutually or connect the p-side electrodes 15 mutually.

The connection member 20 extends in the x direction and is provided to overlap a portion of the first solar cell 10a and a portion of the second solar cell 10b in the direction of thickness (z direction). Therefore, the back surface 13 of the first solar cell 10a is provided with an exposed area 17 not overlapping the connection member 20, and the back surface 13 and the second encapsulant 46 are directly in contact in the exposed area 17. The exposed area 17 corresponds to an area in the back surface 13 where an n-side finger electrode 14b and a p-side finger electrode 15b (see FIG. 3 described later) are provided.

The connection member 20 includes an insulation layer 22 and a conductive layer 24. The insulation layer 22 is a substrate made of an insulative resin material or the like. The insulation layer 22 may be a flexible substrate having ductility or flexibility or a rigid substrate having certain rigidity. It is preferred that the thickness of the insulation layer 22 be 10 μm-200 μm. The conductive layer 24 is a wiring layer provided on the insulation layer 22 and is made of a conductive metallic material. The conductive layer 24 is made of, for example, a material having high conductivity such as copper (Cu) and silver (Ag). The conductive layer 24 may include a plating layer of gold (Au), Ni (nickel), or the like. The conductive layer 24 is provided on the entirety of the insulation layer 22. It is preferred that the thickness of the conductive layer 24 be 5 μm-50 μm. The conductive layer 24 may be provided only in a part on the insulation layer 22. The conductive layer 24 may be formed in a part on the insulation layer 22 in a net pattern, a grid pattern, or a stripe pattern. The connection member 20 may be formed only by the conductive layer 24 and may be, for example, a metallic foil such as a copper foil and an aluminum (Al) foil. The thickness of the metallic foil may be 10 μm-100 μm.

The connection member 20 is provided such that the conductive layer 24 faces the solar cell 10. Therefore, the intermediate insulation part 30, the first insulation part 31, the second insulation part 32, the first conductive adhesion part 34, and the second conductive adhesion part 35 are provided on the conductive layer 24 and are in contact with the conductive layer 24. Meanwhile, the insulation layer 22 is provided to face the second protective member 42.

The intermediate insulation part 30 is provided on the surface of the connection member 20 and is provided between two solar cells connected by the connection member 20. The intermediate insulation part 30 is provided at, for example, a position between the first solar cell 10a and the second solar cell 10b. The intermediate insulation part 30 is provided at a distance from at least one of the first solar cell 10a and the second solar cell 10b and is provided to create a gap 48 from at least one of the first solar cell 10a and the second solar cell 10b. It is preferred that the intermediate insulation part 30 be provided at a distance from both the first solar cell 10a and the second solar cell 10b, and it is preferred that a gap is created both from the first solar cell 10 and the second solar cell 10b.

The first insulation part 31 is provided between the first solar cell 10a and the connection member 20 and is provided at a position on the surface of the connection member 20 opposite to the intermediate insulation part 30, sandwiching the first conductive adhesion part 34. The first insulation part 31 prevents the first solar cell 10a and the connection member 20 from being in contact with each other outside the adhesion area where the first conductive adhesion part 34 is provided. The first insulation part 31 is provided to prevent conduction due to the contact between the p-side electrode 15 of the first solar cell 10a and the connection member 20.

The second insulation part 32 is provided between the second solar cell 10b and the connection member 20 and is provided at a position on the surface of the connection member 20 opposite to the intermediate insulation part 30, sandwiching the second conductive adhesion part 35. The second insulation part 32 prevents the second solar cell 10b and the connection member 20 from being in contact with each other outside the adhesion area where the second conductive adhesion part 35 is provided. The second insulation part 32 is provided to prevent conduction due to the contact between the n-side electrode 14 of the second solar cell 10b and the connection member 20.

The intermediate insulation part 30, the first insulation part 31, and the second insulation part 32 are made of an insulative material and is made of, for example, a resin material such as an epoxy resin, an acrylic resin, and a urethane resin. The intermediate insulation part 30, the first insulation part 31, and the second insulation part 32 may be made of the same material or different materials. The intermediate insulation part 30, the first insulation part 31, and the second insulation part 32 may contain insulative particles. The intermediate insulation part 30, the first insulation part 31, and the second insulation part 32 may contain particles of titania (TiO₂), alumina (Al₂O₃), or the like and may be configured to present a white color. The intermediate insulation part 30, the first insulation part 31, and the second insulation part 32 may be configured to contain insulative black particles of carbon black or the like to present a black color.

The first conductive adhesion part 34 is provided between the first solar cell 10a and the connection member 20 and electrically connects the n-side electrode 14 of the first solar cell 10a and the connection member 20. The first conductive adhesion part 34 is provided at a position on the connection member 20 between the intermediate insulation part 30 and the first insulation part 31.

The second conductive adhesion part 35 is provided between the second solar cell 10b and the connection member 20 and electrically connects the p-side electrode 15 of the second solar cell 10b and the connection member 20. The second conductive adhesion part 35 is provided at a position on the connection member 20 between the intermediate insulation part 30 and the second insulation part 32.

The first conductive adhesion part 34 and the second conductive adhesion part 35 contain an adhesive resin base and conductive particles. The first conductive adhesion part 34 and the second conductive adhesion part 35 contain, as a binder, a thermosetting resin such as an epoxy resin, an acrylic resin, and a urethane resin and contain, as conductive particles, silver (Ag) particles, tin-bismuth (SnBi) based particles, nickel (Ni) particles, or the like.

The first protective member 40 is provided on the light receiving surface side of the solar cell module 100. The first protective member 40 may be formed by using a translucent and water shielding glass plate, a translucent plastic plate, or the like. The thickness of the first protective member 40 is, for example, 1 mm-10 mm. The second protective member 42 is provided on the back surface side of the solar cell module 100. The second protective member 42 may be formed by using a glass plate or a resin substrate of polyethylene terephthalate (PET) or the like. The thickness of the second protective member 42 is, for example, 50 μm-200 μm. The first protective member 40 may be a film of fluororesin or PET-based resin and may have a thickness of 10 μm-1 mm.

The first encapsulant 44 is provided between the first protective member 40 and the cell string 50. The second encapsulant 46 is provided between the second protective member 42 and the cell string 50. The first encapsulant 44 and the second encapsulant 46 seals the cell string 50 between the first protective member 40 and the second protective member 42. The first encapsulant 44 enters a space between adjacent solar cells 10 or the gap 48 between the solar cell 10 and the intermediate insulation part 30 to prevent bubbles from being produced in these spaces. The first encapsulant 44 and the second encapsulant 46 may be formed by using a resin film of ethylene-vinyl acetate copolymer (EVA), polyvinyl butyral (PVB), polyimide, or the like. The thickness of the first encapsulant 44 and the second encapsulant 46 is, for example, 100μ-800 μm. The second encapsulant 46 may contain particles of titania (TiO₂), alumina (Al₂O₃), or the like for scattering incident light.

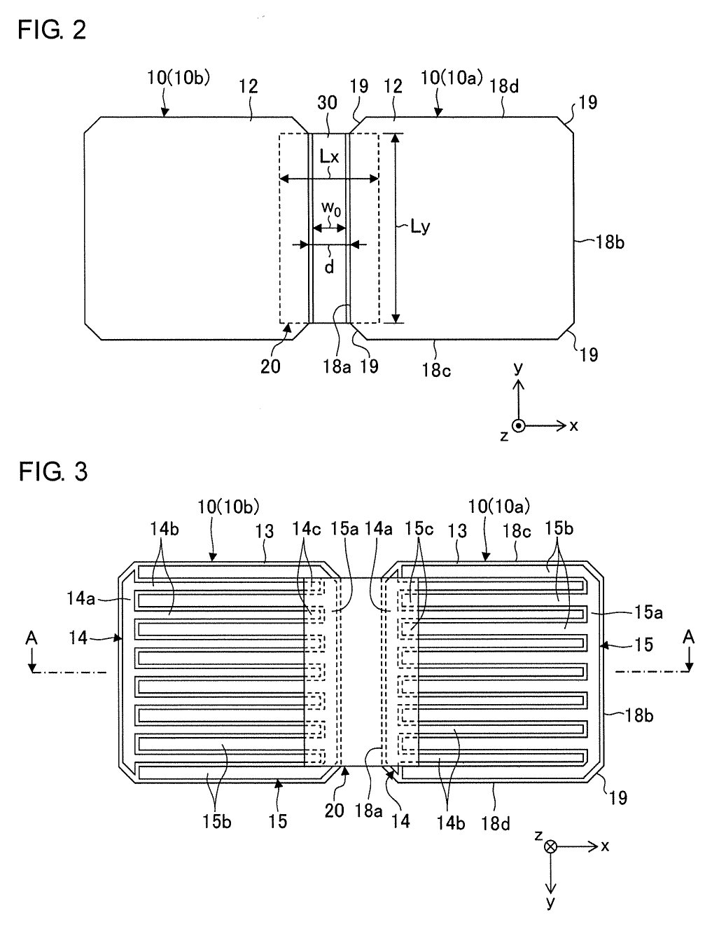

FIG. 2 is a plan view showing the solar cells 10 connected by the connection member 20 and shows features of the solar cells 10 as viewed from the light receiving surface 12. The solar cell 10 has a substantially rectangular outer circumferential shape and has an octagonal outer circumferential shape chamfered at the four corners. The outer circumference of the solar cell 10 is comprised of four longer sides 18a, 18b, 18c, and 18d (generically referred to as longer sides 18) extending in the x direction and the y direction, and four shorter sides 19 provided between the respective longer sides 18.

The connection member 20 extends in the x direction and is provided to overlap a portion of the first solar cell 10a and a portion of the second solar cell 10b. To put it in another way, another portion of each of the first solar cell 10a and the second solar cell 10b does not overlap the connection member 20 and defines the exposed area 17 (see FIG. 1) in which the back surface 13 is exposed. The length Lx of the connection member 20 in the x direction is longer than the interval d between the adjacent solar cells 10. The connection member 20 extends in the y direction and is provided at a position corresponding to the longer side 18a of the solar cell 10 extending in the y direction. The length Ly of the connection member 20 in the y direction is equal to the longer side 18a extending in the y direction. The length Ly of the connection member 20 in the y direction may be longer or shorter than the longer side 18a extending in the y direction.

The intermediate insulation part 30 is provided at a distance from the outer circumference of the adjacent solar cells 10 and is provided so as not to be in contact with the outer circumference of the solar cells 10. Therefore, the width w0 of the intermediate insulation part 30 in the x direction is shorter than the interval d between the adjacent solar cells 10. The intermediate insulation part 30 extends in the y direction over the entirety of the connection member 20 and is provided such that the width thereof in the y direction is equal to the length Ly of the connection member 20 in the y direction.

FIG. 3 is a plan view showing the solar cells 10 connected by the connection member 20 and shows features of the solar cells 10 as viewed from the back surface 13. FIG. 3 shows a detailed configuration of the n-side electrode 14 and the p-side electrode 15 provided on the back surface 13. FIG. 1 above corresponds to an A-A cross section of FIG. 3.

The n-side electrode 14 includes an n-side bus bar electrode 14a extending in the y direction and a plurality of n-side finger electrodes 14b extending in the x direction and is formed in a comb-tooth pattern. The n-side bus bar electrode 14a is provided in the vicinity of the outer circumference of the solar cell 10 and is provided along one longer side 18a extending in the y direction. The plurality of n-side finger electrodes 14b extend from the n-side bus bar electrode 14a in the x direction and are provided at intervals in the y direction.

The p-side electrode 15 includes a p-side bus bar electrode 15a extending in the y direction and a plurality of p-side finger electrodes 15b extending in the x direction and is formed in a comb-tooth pattern. The p-side bus bar electrode 15a is provided in the vicinity of the outer circumference of the solar cell 10 and is provided along another longer side 18b extending in the y direction. The p-side bus bar electrode 15a is provided along the longer side 18b opposite to the longer side 18a in which the n-side bus bar electrode 14a is provided. The p-side finger electrodes 15b extend from the p-side bus bar electrode 15a in the x direction and are provided at intervals in the y direction. The plurality of n-side finger electrodes 14b and the plurality of p-side finger electrodes 15b are provided alternately in the y direction.

The connection member 20 is provided to overlap the n-side bus bar electrode 14a of the first solar cell 10a and is provided to overlap an end 15c of the p-side finger electrode 15b of the first solar cell 10a. The end 15c of the p-side finger electrode 15b is a portion of the p-side finger electrode 15b positioned in the vicinity of the n-side bus bar electrode 14a. The connection member 20 need not necessarily be provided overlap the end 15c of the p-side finger electrode 15b and may be provided to overlap the n-side bus bar electrode 14a.

The connection member 20 is provided to overlap the p-side bus bar electrode 15a of the second solar cell 10b and is provided to overlap an end 14c of the n-side finger electrode 14b of the second solar cell 10b. The end 14c of the n-side finger electrode 14b is a portion of the n-side finger electrode 14b positioned in the vicinity of the p-side bus bar electrode 15a. The connection member 20 need not necessarily be provided to overlap the end 14c of the n-side finger electrode 14b and may be provided to overlap the p-side bus bar electrode 15a.

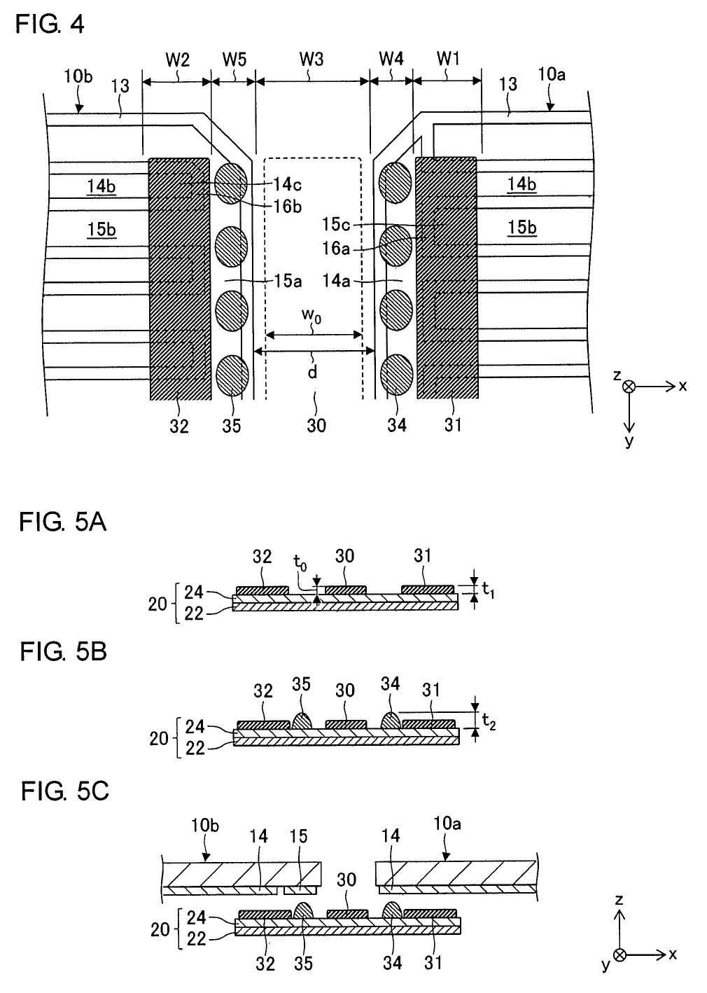

FIG. 4 is a plan view schematically showing an arrangement of the conductive adhesion part and the insulation part. FIG. 4 shows features on the side of the back surface 13 viewed when the connection member 20 is removed and corresponds to an enlarged view of some of the features in FIG. 3. The intermediate insulation part 30 is provided in a third area W3 defined between the adjacent solar cells 10. The intermediate insulation part 30 is formed continuously over the range of the connection member 20 in the y direction.

The first insulation part 31 is provided in a first area W1 defined in a part of the back surface 13 of the first solar cell 10a. The first area W1 includes a range in which the end 15c of the p-side finger electrode 15b is positioned and a range in which a first isolation groove 16a between the n-side bus bar electrode 14a and the p-side finger electrode 15b is positioned. The first area W1 may include a part of the range in which the n-side bus bar electrode 14a is provided. The first insulation part 31 is formed continuously over the range of the connection member 20 in the y direction. By providing the first insulation part 31 in this way, a short circuit due to the contact between the connection member 20 and the end 15c of the p-side finger electrode 15b is suitably prevented.

The second insulation part 32 is provided in a second area W2 defined in a part of the back surface 13 of the second solar cell 10b. The second area W2 includes a range in which the end 14c of the n-side finger electrode 14b is positioned and a range in which a second isolation groove 16b between the p-side bus bar electrode 15a and the n-side finger electrode 14b is positioned. The second area W2 may include a part of the range in which the p-side bus bar electrode 15a is provided. The second insulation part 32 is formed continuously over the range of the connection member 20 in the y direction. By providing the second insulation part 32 in this way, a short circuit due to the contact between the connection member 20 and the end 14c of the n-side finger electrode 14b is suitably prevented.

The first conductive adhesion part 34 is provided in a fourth area W4 defined between the first area W1 and the third area W3. The fourth area W4 is defined to include at least a part of the range in which the n-side bus bar electrode 14a and is defined to exclude the range in which the p-side finger electrode 15b is provided. The first conductive adhesion part 34 is provided as spots provided at intervals in the y direction. By providing the first conductive adhesion part 34 as spots, the first conductive adhesion part 34 is inhibited from protruding outside the fourth area W4 when the first conductive adhesion part 34 is sandwiched between the first solar cell 10a and the connection member 20. This prevents a short circuit between the n-side electrode 14 and the p-side electrode 15 in the first solar cell 10a. The first conductive adhesion part 34 may be formed in a continuous straight line.

The second conductive adhesion part 35 is provided in a fifth area W5 defined between the second area W2 and the third area W3. The fifth area W5 is defined to include at least a part of the range in which the p-side bus bar electrode 15a is provided and is defined to exclude the range in which the n-side finger electrode 14b is provided. The second conductive adhesion part 35 is provided as spots provided at intervals in the y direction. By providing the second conductive adhesion part 35 as spots, the second conductive adhesion part 35 is inhibited from protruding outside the fifth area W5 when the second conductive adhesion part 35 is sandwiched between the second solar cell 10b and the connection member 20. This prevents a short circuit between the n-side electrode 14 and the p-side electrode 15 in the second solar cell 10b. The second conductive adhesion part 35 may be formed in a continuous straight line.

A description will now be given of a method of manufacturing the solar cell module 100. FIGS. 5A-5C are cross-sectional views schematically showing steps of manufacturing the solar cell module 100. First, as shown in FIG. 5a, the intermediate insulation part 30, the first insulation part 31, and the second insulation part 32 are formed on the conductive layer 24 of the connection member 20. As shown in FIG. 4, the intermediate insulation part 30, the first insulation part 31, and the second insulation part 32 are formed continuously in the y direction.

The intermediate insulation part 30, the first insulation part 31, and the second insulation part 32 are formed by coating the connection member 20 with an insulative resin paste. The insulative resin paste may be applied by using an ejection means such as a dispenser or applied by using a printing technique such as screen printing and offset printing.

The intermediate insulation part 30, the first insulation part 31, and the second insulation part 32 may be formed simultaneously or formed in separate steps. In the case a resin paste is applied by using a dispenser, for example, three dispensers corresponding to the positions where the intermediate insulation part 30, the first insulation part 31, and the second insulation part 32 are formed may be used for coating. Alternatively, one dispenser may be used to form the intermediate insulation part 30, the first insulation part 31, and the second insulation part 32 in sequence.

In the case of applying a resin paste by using a printing technique, one printing plate may be used to form the intermediate insulation part 30, the first insulation part 31, and the second insulation part 32 simultaneously, or two or more printing plates may be used to form the parts separately. For example, the first insulation part 31 and the second insulation part 32 may be formed by using the first printing plate and temporarily hardened, and then the intermediate insulation part 30 may be formed by using the second printing plate. The sequence may be reversed, and the first insulation part 31 and the second insulation part 32 may be formed after forming the intermediate insulation part 30.

Before the first solar cell 10a and the second solar cell 10b are provided, the first insulation part 31 and the second insulation part 32 are formed such that a thickness t1 thereof from the connection member 20 is substantially equal to a thickness t0 of the intermediate insulation part 30. Alternatively, the thickness t0 of the intermediate insulation part 30 from the connection member 20 may differ from the thickness t1 of the first insulation part 31 and the second insulation part 32. For example, the intermediate insulation part 30 is provided at a location not overlapping the solar cell 10 so that the thickness thereof may be larger than that of the first insulation part 31 and the second insulation part 32. Still alternatively, the thickness t0 of the intermediate insulation part 30 may be smaller than the thickness t1 of the first insulation part 31 and the second insulation part 32.

Subsequently, as shown in FIG. 5B, the first conductive adhesion part 34 and the second conductive adhesion part 35 are formed on the conductive layer 24 of the connection member 20. The first conductive adhesion part 34 and the second conductive adhesion part 35 may be formed by coating the connection member 20 with a conductive resin paste. As in the case of the intermediate insulation part 30 described above, the conductive resin paste may be applied by using an ejection means such as a dispenser or applied by using a printing technique such as screen printing and offset printing. As shown in FIG. 4, the first conductive adhesion part 34 and the second conductive adhesion part 35 are provided as spots provided at intervals in the y direction.

The first conductive adhesion part 34 is formed in an area between the intermediate insulation part 30 and the first insulation part 31, and the second conductive adhesion part 35 is formed in an area between the intermediate insulation part 30 and the second insulation part 32. By forming the intermediate insulation part 30, the first insulation part 31, and the second insulation part 32 first, the first conductive adhesion part 34 and the second conductive adhesion part 35 are prevented from being attached to portions that should be insulated to result in a short circuit.

As shown in FIG. 5C, the connection member, in which the intermediate insulation part 30, the first insulation part 31, the second insulation part 32, the first conductive adhesion part 34, and the second conductive adhesion part 35 are provided, is then mounted to the first solar cell 10a and the second solar cell 10b. In this process, the first solar cell 10a is provided on the first insulation part 31 and the first conductive adhesion part 34, and the second solar cell 10b is provided on the second insulation part 32 and the second conductive adhesion part 35. The stack may be upside down, and the first insulation part 31 and the first conductive adhesion part 34 may be provided on the first solar cell 10a, and the second insulation part 32 and the second conductive adhesion part 35 may be provided on the second solar cell 10b. This causes the n-side electrode 14 of the first solar cell 10a to be adhesively bonded to the first conductive adhesion part 34 and causes the p-side electrode 15 of the second solar cell 10b to be adhesively bonded to the second conductive adhesion part 35. This completes the cell string 50.

When the first solar cell 10a and the connection member 20 are adhesively bonded, the first conductive adhesion part 34 is sandwiched between the first solar cell 10a and the connection member 20 and spreads to a surrounding area. In this process, the intermediate insulation part 30 and the first insulation part 31 present a wall to limit the range in which the first conductive adhesion part 34 spreads. Similarly, when the second solar cell 10b and the connection member 20 are adhesively bonded, the intermediate insulation part 30 and the second insulation part 32 present a wall to limit the range in which the second conductive adhesion part 35 spreads. This prevents the first conductive adhesion part 34 and the second conductive adhesion part 35 from exuding in an area between the adjacent solar cells 10.

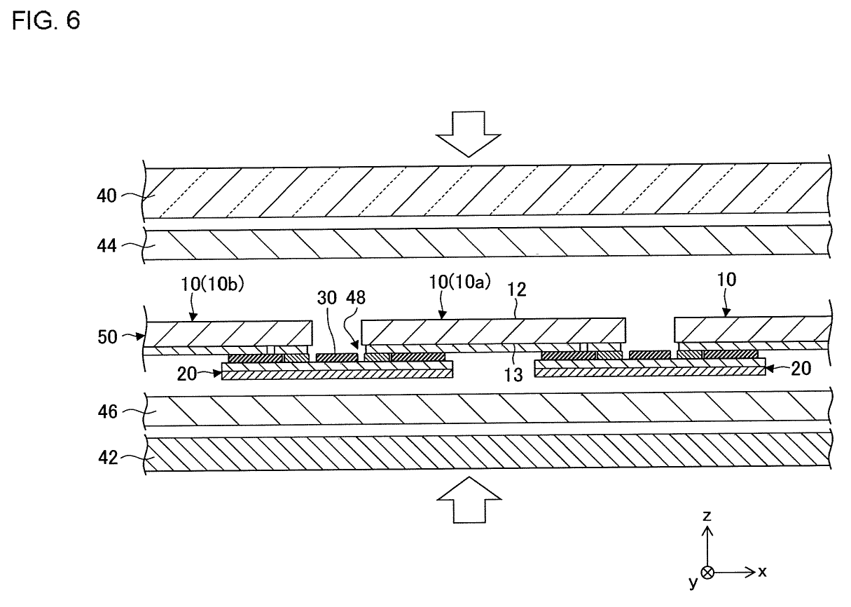

FIG. 6 is a cross-sectional view schematically showing a step of manufacturing the solar cell module 100 and shows a step of encapsulating the cell string 50. The first protective member 40 and the first encapsulant 44 are provided on the side of the light receiving surface 12 of the solar cells connected by the connection member, and the second protective member 42 and the second encapsulant 46 are provided on the side of the back surface 13. The first protective member 40 and the second protective member 42 are heated while a pressure is applied therebetween so as to fuse the first encapsulant 44 and the second encapsulant 46. In this process, a portion of the first encapsulant 44 fused enters a gap 48 between the solar cell 10 and the intermediate insulation part 30 to seal the space between the adjacent solar cells 10 by the first encapsulant 44. This completes the solar cell module 100 shown in FIG. 1.

According to the solar cell module 100 configured as described above, the adjacent solar cells 10 are prevented from coming into contact with each other due to the proximity, by providing the intermediate insulation part 30 between the adjacent solar cells 10. This also prevents deformation such as bending of the connection member 20 associated with the proximity of the adjacent solar cells 10. It also prevents the deformed connection member 20 from coming into contact with a portion (e.g., the photoelectric conversion part 11) other than the electrode that should be connected. Thus, the embodiment enhances the reliability by preventing undesired deformation or contact of members forming the solar cell module 100 and inhibiting degradation or damage associated with deformation or contact of members.

According to the embodiment, the stress applied to the conductive layer 24 of the connection member 20 from the insulation layer 22, which has a relatively large coefficient of thermal expansion, is mitigated by providing the intermediate insulation part 30 on the conductive layer 24. By mitigating the stress applied to the conductive layer 24, the likelihood that the conductive layer 24 is damaged by being excessively expanded or contracted is reduced. Further, by providing the intermediate insulation part 30 on the conductive layer 24, direct contact between the conductive layer 24 and the first encapsulant 44 is prevented, and metal ions (e.g., copper ions) of the conductive layer 24 are inhibited from spreading to the first encapsulant 44. This inhibits the first encapsulant 44 from being degraded by spreading metal ions.

According to the embodiment, intimacy of contact between the connection member 20 and the first encapsulant 44 is improved, and the first encapsulant 44 is prevented from being exfoliated from the connection member 20, by providing the intermediate insulation part 30 on the connection member 20. Further, by providing the gap 48 between the adjacent solar cells 10 and the intermediate insulation part 30, the space between the solar cell 10 and the connection member 20 is filled with the first encapsulant 44. This prevents bubbles from remaining between the first protective member 40 and the second protective member 42 and improves the appearance of the first protective member 40 viewed from above.

According to the embodiment, the design of the first protective member 40 viewed from above is improved by providing the intermediate insulation part 30 between the adjacent solar cells 10. If the intermediate insulation part 30 is not provided and the conductive layer 24 of the connection member 20 is exposed, the conductive layer 24 made of a metal is seen between the solar cells 10, and the design is impaired. Meanwhile, by providing the intermediate insulation part 30 on the conductive layer 24 and coloring the intermediate insulation part 30 white, which is also the color of the second protective member 42, the connection member 20 is substantially made invisible, and an outer design, in which the outer circumference of each solar cell 10 is bounded by a white frame, is produced. Alternatively, by coloring the intermediate insulation part 30 black, which is also the color of the solar cell 10, an outer design, in which the solar cell 10 and the connection member 20 appear integrated, is produced.

An embodiment of the disclosure is defined as follows. A solar cell module (100) according to an embodiment includes:

a first solar cell (10a) in which an n-side electrode (14) and a p-side electrode (15) are provided on one principal surface (back surface 13);

a second solar cell (10b) in which an n-side electrode (14) and a p-side electrode (15) are provided on one principal surface (back surface 13);

a connection member (20) that connects the one principal surface (back surface 13) of the first solar cell (10a) and the one principal surface (back surface 13) of the second solar cell (10b) and electrically connects the n-side electrode (14) of the first solar cell (10a) and the p-side electrode (15) of the second solar cell (10b);

a first conductive adhesion part (34) that connects the n-side electrode (14) of the first solar cell (10a) with the connection member (20);

a second conductive adhesion part (35) that connects the p-side electrode (15) of the second solar cell (10b) with the connection member (20); and

an intermediate insulation part (30) that is provided at a position on a surface of the connection member (20) between the first conductive adhesion part (34) and the second conductive adhesion part (35) and is provided at a distance from at least one of the first solar cell (10a) and the second solar cell (10b).

The solar cell module may further include: a first insulation part (31) provided between the first solar cell (10a) and the connection member (20) and provided at a position on the surface of the connection member (20) opposite to the intermediate insulation part (30), sandwiching the first conductive insulation part (34); and

a second insulation part (32) provided between the second solar cell (10b) and the connection member (20) and provided at a position on the surface of the connection member (20) opposite to the intermediate insulation part (30), sandwiching the second conductive insulation part (35).

The intermediate insulation part (30) may be provided at a distance from both the first solar cell (10a) and the second solar cell (10b).

A method of manufacturing a solar cell module (100) according to an embodiment includes:

forming an intermediate insulation part (30) on a surface of a connection member (20) for connecting one principal surface (back surface 13) of a first solar cell (10a) including an n-side electrode (14) and a p-side electrode (15) on the one principal surface (back surface 13) and one principal surface (back surface 13) of a second solar cell (10b) including an n-side electrode (14) and a p-side electrode (15) on the one principal surface (back surface 13);

connecting, via a first conductive adhesion part (34), the n-side electrode (14) of the first solar cell (10a) at a position on the surface of the connection member (20) different from a position of the intermediate insulation part (30); and

connecting, via a second conductive adhesion part (35), the p-side electrode (15) of the second solar cell (10b) at a position on the surface of the connection member (20) opposite to the first conductive adhesion part (34), sandwiching the intermediate insulation part (30).

The first conductive adhesion part (34) may be formed on the surface of the connection member (20) and be then adhesively bonded to the n-side electrode (14) of the first solar cell (10a), and

the second conductive adhesion part (35) may be formed on the surface of the connection member (20) and is then adhesively bonded to the p-side electrode (15) of the second solar cell (10b).

The method may further include: forming a first insulation part (31) at a position on the surface of the connection member (20) opposite to the intermediate insulation part (30), sandwiching an adhesion area of the first conductive adhesion part (34) before connecting the first solar cell (10a) and the connection member (20); and

forming a second insulation part (32) at a position on the surface of the connection member (20) opposite to the intermediate insulation part (30), sandwiching an adhesion area of the second conductive adhesion part (35) before connecting the second solar cell (10b) and the connection member (20).

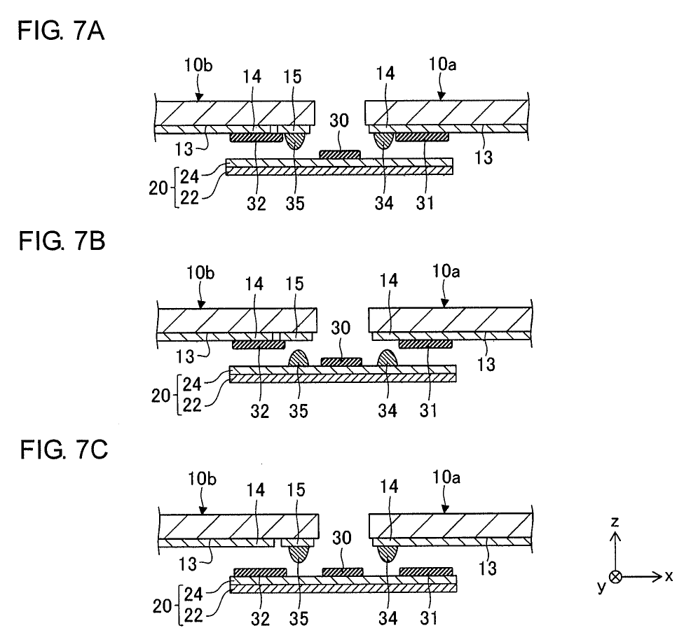

FIGS. 7A-7C are cross-sectional views schematically showing steps of manufacturing the solar cell module 100 according to a variation. In the embodiment above, it is described that the first insulation part 31, the second insulation part 32, the first conductive adhesion part 34, and the second conductive adhesion part 35 are formed on the connection member 20 before the solar cell 10 and the connection member 20 are connected. In one variation, at least one of the first insulation part 31, the second insulation part 32, the first conductive adhesion part 34, and the second conductive adhesion part 35 may be formed on the solar cell 10 before the solar cell and the connection member 20 are connected.

In the example of FIG. 7A, the first insulation part 31 and the first conductive adhesion part 34 are formed on the back surface 13 of the solar cell 10a, and the second insulation part 32 and the second conductive adhesion part 35 are formed on the back surface 13 of the solar cell 10b. The intermediate insulation part 30 is formed on the connection member 20. Subsequently, the first solar cell 10a and the second solar cell 10b are adhesively bonded to the connection member 20. According to this variation, the first insulation part 31 and the second insulation part 32 are provided on the back surface 13 of the solar cell 10 before the connection member 20 is adhesively bonded. Therefore, portions where a short circuit could occur can be properly covered by the first insulation part 31 and the second insulation part 32.

In the example of FIG. 7B, the first insulation part 31 is formed on the back surface 13 of the solar cell 10a, and the second insulation part 32 is formed on the back surface of the solar cell 10b. The intermediate insulation part 30, the first conductive adhesion part 34, and the second conductive adhesion part 35 are formed on the connection member 20. Subsequently, the first solar cell 10a and the second solar cell 10b are connected to the connection member 20. As in the example of FIG. 7A, portions of the back surface 13 of the solar cell 10 where a short circuit could occur can be properly covered by the first insulation part 31 and the second insulation part 32 in this variation as well.

In the example of FIG. 7C, the first conductive adhesion part 34 is formed on the n-side electrode 14 of the solar cell 10a, and the second conductive adhesion part 35 is formed on the p-side electrode 15 of the second solar cell 10b. The intermediate insulation part 30, the first insulation part 31, and the second insulation part 32 are formed on the connection member 20. Subsequently, the first solar cell 10a and the second solar cell 10b are formed on the connection member 20. According to this variation, the intermediate insulation part 30, the first insulation part 31, and the second insulation part 32 are formed on the connection member 20 simultaneously so that the manufacturing steps are simplified.

In a method of manufacturing the solar cell module 100 according to an embodiment,

the first conductive adhesion part (34) may be formed on the n-side electrode of the first solar cell (10a) and be then adhesively bonded to the connection member (20), and

the second conductive adhesion part (35) may be formed on the p-side electrode of the second solar cell (10b) and be then adhesively bonded to the connection member (20).

The method of manufacturing the solar cell module 100 according to an embodiment may further include:

forming a first insulation part (31) on at least a part of the p-side electrode (15) of the first solar cell (10a) before connecting the first solar cell (10a) and the connection member (20); and

forming a second insulation part (32) on at least a part of the n-side electrode (14) of the second solar cell (10b) before connecting the second solar cell (10b) and the connection member (20).

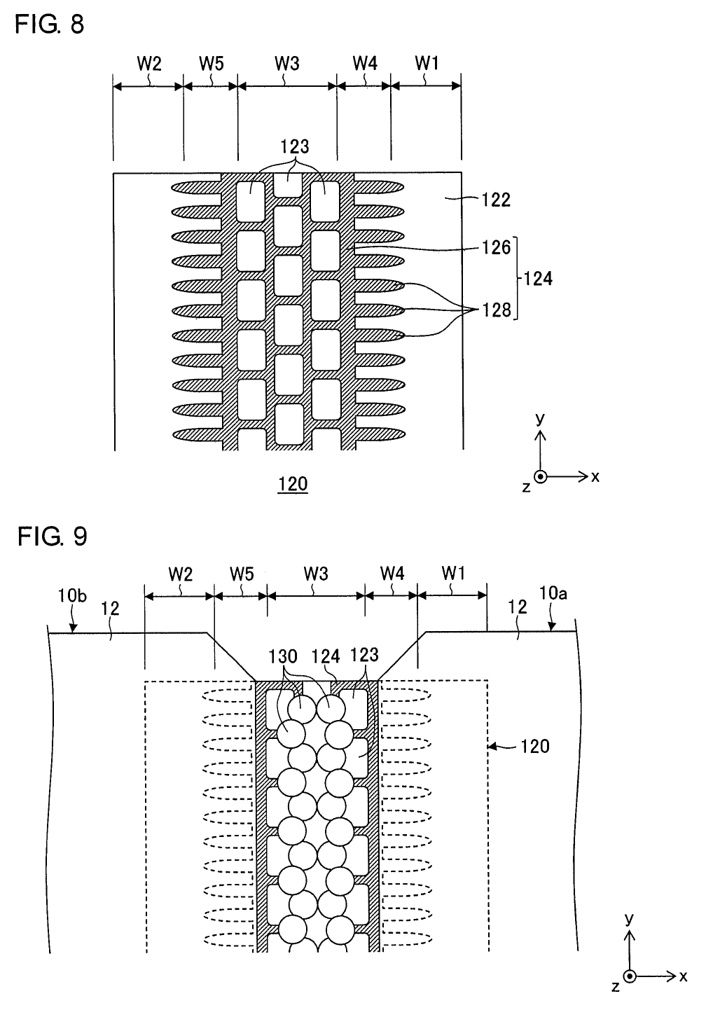

FIG. 8 is a plan view schematically showing a configuration of a connection member 120 according to a variation. The connection member 120 includes an insulation layer 122 and a conductive layer 124. In this variation, the conductive layer 124 is not formed on the entirety of the insulation layer 122 and is provided in a part of the insulation layer 122. The conductive layer 124 includes a main part 126 provided in the third area W3 between the adjacent solar cells 10 and a plurality of projections 128 extending from the main part 126 in the x direction.

The main part 126 is formed on the entirety of the third area W3 in a net pattern or a grid pattern. In the third area W3, a plurality of openings 123, in which the conductive layer 124 is not provided and through which the insulation layer 122 is exposed, are provided. The projections 128 extend in the x direction from the third area W3 to the fourth area W4 and from the third area W3 to the fifth area W5. The plurality of projections 128 are provided at intervals in the y direction. The conductive layer 124 is not provided in at least in a part of the first area W1 and the second area W2. This is because the first area W1 and the second area W2 are an area where the first insulation part 31 or the second insulation part 32 is provided, and there is no need to provide the conductive layer 124.

According to this variation, the conductive layer 124 is provided in a part on the insulation layer 122 so that occurrence of a stress due to a difference in coefficients in thermal expansion between the insulation layer 122 and the conductive layer 124 is mitigated. This prevents disconnection in the conductive layer 124 caused by an excessive stress on the conductive layer 124.

FIG. 9 is a plan view schematically showing a configuration of an intermediate insulation part 130 according to a variation. In the embodiment described above, the intermediate insulation part 30 is shown as being provided in the third area W3 so as to be continuous in the x direction and the y direction. In this variation, the intermediate insulation part 130 is not formed continuously, but the intermediate insulation part 130 is formed in a part. The intermediate insulation part 130 is provided at a position that covers the conductive layer 124 provided in a net pattern or a grid pattern and is provided to avoid the opening 123 where the conductive layer 124 is not provided. According to this variation, the resin paste used for formation of the intermediate insulation part 130 is reduced by providing the intermediate insulation part 130 in part. Meanwhile, the stress applied to the conductive layer 124 is mitigated, and damage to the conductive layer 124 is suitably prevented, by providing the intermediate insulation part 130 on the conductive layer 124 provided in a part. Further, the conductive layer 124 is made invisible in appearance, and the design of the solar cell module 100 is improved, by covering the conductive layer 124.

In the solar cell module (100) according to an embodiment,

the connection member (20) may include an insulation layer (22) and a conductive layer (24) provided in a part on the insulation layer (22), and

the intermediate insulation part (30) may be provided at a position on the connection member that covers the conductive layer (24).

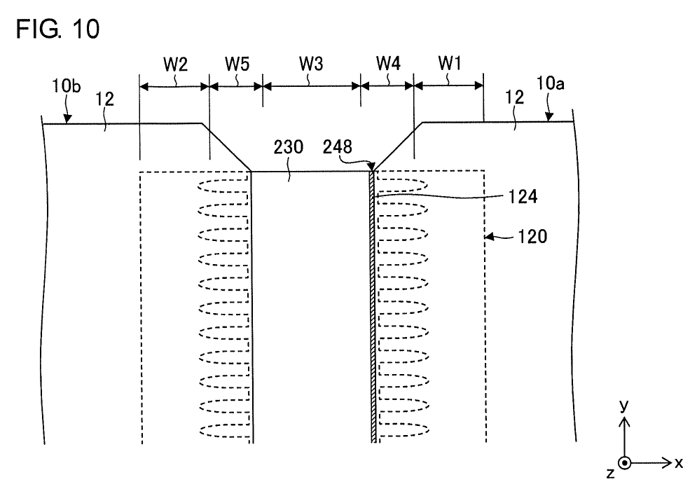

FIG. 10 is a plan view schematically showing a configuration of an intermediate insulation part 230 according to another variation. In the embodiment shown in FIG. 2 above, it is described that the intermediate insulation part 30 is provided such that intermediate insulation part 30 is neither in contact with the first solar cell 10a nor with the second solar cell 10b. In this variation, a gap 248 is provided between the first solar cell 10a and the intermediate insulation part 230, but no gaps are provided between the second solar cell 10b and the intermediate insulation part 230 so that the second solar cell 10b and the intermediate insulation part 230 are in contact with each other. In a further variation, the first solar cell 10a and the intermediate insulation part 230 are in contact with each other, but a gap is provided between the second solar cell 10b and the intermediate insulation part 230. In other words, a gap is provided between the intermediate insulation part 230 and one of the adjacent solar cells 10, but no gaps are provided between the intermediate insulation part 230 and the other of the adjacent solar cells 10. According to this variation, the conductive layer 124 of the connection member 120 is more suitably protected by increasing the area covered by the intermediate insulation part 230 as much as possible.

The embodiment of the present invention is not limited to those described above and appropriate combinations or replacements of the features of the embodiment and the variations are also encompassed by the present invention.

In the embodiment and the variation above, it is described that the intermediate insulation part 30, the first insulation part 31, and the second insulation part 32 are formed by using an insulative resin paste. In a further variation, at least one of the intermediate insulation part 30, the first insulation part 31, and the second insulation part 32 may be formed by pasting a tape made of an insulative material. At least one of the intermediate insulation part 30, the first insulation part 31, and the second insulation part 32 may be formed by applying an insulative fluororesin- based coating agent capable of transforming the surface wettability.

In the embodiment and the variation above, it is described that the first conductive adhesion part 34 and the second conductive adhesion part 35 are formed by using a conductive resin paste. In a further variation, the at least one of the first conductive adhesion part 34 and the second conductive adhesion part 35 may be formed by pasting a conductive tape.

It should be understood that the invention is not limited to the above-described embodiments and modifications but may be further modified into various forms on the basis of the spirit of the invention. Additionally, those modifications are included in the scope of the invention.

What is claimed is:

1. A solar cell module comprising:
a first solar cell having a first principal surface on which both an n-side electrode and a p-side electrode are provided;
a second solar cell having a second principal surface on which both an n-side electrode and a p-side electrode are provided;
a connection member that connects the first principal surface and the second principal surface and electrically connects the n-side electrode of the first solar cell and the p-side electrode of the second solar cell;
a first conductive adhesion part that connects the n- side electrode of the first solar cell with the connection member;
a second conductive adhesion part that connects the A- side electrode of the second solar cell with the connection member; and
an intermediate insulation part that is provided at a position on a surface of the connection member between the first conductive adhesion part and the second conductive adhesion part and is provided at a distance from at least one of the first solar cell and the second solar cell.

2. The solar cell module according to claim 1, further comprising:
a first insulation part provided between the first solar cell and the connection member and provided at a position on the surface of the connection member opposite to the intermediate insulation part, sandwiching the first conductive insulation part; and
a second insulation part provided between the second solar cell and the connection member and provided at a position on the surface of the connection member opposite to the intermediate insulation part, sandwiching the second conductive insulation part.

3. The solar cell module according to claim 1, wherein
the intermediate insulation part is provided at a distance from both the first solar cell and the second solar cell.

4. The solar cell module according to claim 1, wherein
the connection member includes an insulation layer and a conductive layer provided in a selected part on the insulation layer, and
the intermediate insulation part is provided at a selected position on the connection member that covers the conductive layer.

5. A method of manufacturing a solar cell module, comprising:
forming an intermediate insulation part on a surface of a connection member for connecting a first principal surface of a first solar cell on which both an n-side electrode and a p-side electrode are provided and a second principal surface of a second solar cell on which both an n-side electrode and a p-side electrode are provided;
connecting, via a first conductive adhesion part, the n-side electrode of the first solar cell at a position on the surface of the connection member different from a position of the intermediate insulation part; and
connecting, via a second conductive adhesion part, the p-side electrode of the second solar cell at a position on the surface of the connection member opposite to the first conductive adhesion part, sandwiching the intermediate insulation part.

6. The method of manufacturing a solar cell module according to claim 5, wherein
the first conductive adhesion part is formed on the surface of the connection member and is then adhesively bonded to the n-side electrode of the first solar cell, and
the second conductive adhesion part is formed on the surface of the connection member and is then adhesively bonded to the p-side electrode of the second solar cell.

7. The method of manufacturing a solar cell module according to claim 5, wherein
the first conductive adhesion part is formed on a surface of the n-side electrode of the first solar cell and is then adhesively bonded to the connection member, and
the second conductive adhesion part is formed on a surface of the p-side electrode of the second solar cell and is then adhesively bonded to the connection member.

8. The method of manufacturing a solar cell module according to claim 5, further comprising:
forming a first insulation part at a position on the surface of the connection member opposite to the intermediate insulation part, sandwiching an adhesion area of the first conductive adhesion part before connecting the first solar cell and the connection member; and
forming a second insulation part at a position on the surface of the connection member opposite to the intermediate insulation part, sandwiching an adhesion area of the second conductive adhesion part before connecting the second solar cell and the connection member.

9. The method of manufacturing a solar cell module according to any one of claim 5, further comprising:
forming a first insulation part on at least a part of the p-side electrode of the first solar cell before connecting the first solar cell and the connection member; and
forming a second insulation part on at least a part of the n-side electrode of the second solar cell before connecting the second solar cell and the connection member.
